(19) United States
(12) Patent Application Publication
(10) Pub. No.: US 2024/0110054 A1
(43) Pub. Date: Apr. 4, 2024

(54) Composite article based on a thermoplastic matrix incorporating at least one transducer comprising a piezoelectric polymer

(71) Applicant: ARKEMA FRANCE, COLOMBES (FR)

(72) Inventors: Fabrice DOMINGUES DOS SANTOS, Colombes Cedex (FR); Thibaut SOULESTIN, Pierre-Benite Cedex (FR); Gilles FRANCOIS, Pierre-Benite Cedex (FR); Pierre GERARD, Lacq (FR)

(73) Assignee: ARKEMA FRANCE, COLOMBES (FR)

(21) Appl. No.: 18/267,757

(22) PCT Filed: Dec. 15, 2021
(86) PCT No.: PCT/FR2021/052350

§ 371 Date: Jun. 15, 2023

(30) Foreign Application Priority Data
Dec. 16, 2020 (FR) FR2013378

(51) Int. Cl. C08L 33/12; B06B 1/06; H10N 30/00; H10N 30/098; H10N 30/857

(52) U.S. Cl. CPC C08L 33/12; B06B 1/0688; H10N 30/098; H10N 30/1061; H10N 30/857; C08L 2203/20

(57) ABSTRACT

A composite article including at least one electronic system, integrated onto the surface or in the volume of a thermoplastic matrix. The electronic system includes at least one piezoelectric transducer and means for transmitting an electrical signal. The piezoelectric transducer includes a piezoelectric polymer essentially consisting of, or consisting of, repeating units derived from vinylidene fluoride (VDF) and vinylidene trifluoride (TrFE), the molar proportion of the unit derived from TrFE being from 15% to 50% relative to the total number of moles of the units derived from VDF and TrFE. Also, the use of the electronic system and to the use of the article.

### TECHNICAL FIELD

The invention relates to the field of instrumentation of a thermoplastic-based article. More specifically, the invention relates to an article comprising transducers based on piezoelectric polymers.

The article according to the invention may be used for measuring a certain number of properties to be monitored and also for controlling the state and evolution of its structure.

### PRIOR ART

The aim of Structural Health Monitoring (SHM) is to measure certain physical and/or geometric properties of the materials used in a given structure. It generally allows variations in these properties to be detected and predicted, which may notably prove useful for evaluating the damage and/or aging of materials in their operational environment. In certain applications, SHM allows timely prediction of appropriate maintenance actions.

An SHM process generally involves: a) taking dynamic and sampled measurements, periodically or continuously, from a network of sensors, b) extracting the features resulting from the measurements and, c) statistically analyzing these features so as to determine the state of the structure.

Lead zirconium titanate (PZT) ceramics and polyvinylidene fluoride (PVDF) films are two known piezoelectric elements that have been used as transducers in certain SHM applications to date.

PZT wafers with a high piezoelectric constant have both excellent sensitivity as sensors and high displacement capability as actuators. However, they have a number of drawbacks. Firstly, they are rigid and brittle, which means that they cannot be used on materials that are bent and/or subject to high stresses. They are also very heavy, which tends to weigh down the structure on which they are mounted. Furthermore, they are cumbersome due to their thickness of a few millimetres and the need to use electrical cables to connect them. Finally, they often contain heavy metals, such as lead, which may make the recycling of articles comprising them particularly complex, if not impossible.

On the other hand, transducers based on PVDF films have the advantage of having high flexibility, low density and a low cost price, and can be recycled. However, PVDF has a relatively low maximum operating temperature, limited to 80° C. or less, which limits the possibilities for its use under conditions of operation and limits its suitability for incorporation into a material in which certain properties need to be measured.

It is known practice, for example, from Frias, C., et al. “Manufacturing and testing composite overwrapped pressure vessels with embedded sensors.” Materials & Design 31.8 (2010): 4016-4022, to implement a structural monitoring system (SHM) within a Composite Overwrapped Pressure Vessel (COPV). The monitoring system comprises transducers consisting of a PVDF membrane between two silver electrodes connected by electrical wires. The transducers are sandwiched between a liner and a composite reinforcing structure consisting of glass fiber-reinforced polypropylene.

It is also known practice from Rim, Mi-Sun, et al. “Damage assessment of small-scale wind turbine blade using piezoelectric sensors.” Sensors and Smart Structures Technologies for Civil, Mechanical, and Aerospace Systems 2012. Vol. 8345. International Society for Optics and Photonics, 2012, to implement a structural monitoring system (SHM) within a prototype wind turbine blade. The monitoring system comprises transducers consisting of a PVDF membrane between two metal electrodes. The transducers are arranged on the surface of the prototype.

Such arrays of PVDF transducers are particularly bulky and are thus time-consuming to install. In addition, if they are located within the volume of the structure to be tested, this bulk makes them particularly invasive, which is undesirable as they weaken the structure they are intended to monitor.

Objects of the Invention

The object of the present invention is to overcome at least some of the drawbacks of the prior art.

An object of the invention is notably, at least according to certain embodiments, to propose a composite article comprising at least one electronic system with transducers based on piezoelectric polymers having improved sensitivity.

An object of the invention, at least according to certain embodiments, is also to propose a composite article whose electronic system is sparingly invasive, i.e. it disturbs as little as possible the structural performance, notably the mechanical properties, of the article which would not contain said electronic system.

An object of the invention is also to propose, at least according to certain embodiments, a composite article whose electronic system withstands high temperatures.

An object of the invention is also to propose, at least according to certain embodiments, a composite article whose electronic system withstands the stresses exerted on the article.

Finally, an object of the invention is, at least according to certain embodiments, to propose a composite article that can be readily disassembled and recycled, and which is not toxic to the environment or to living beings.

### SUMMARY OF THE INVENTION

According to a first aspect, the invention relates to a composite comprising at least one electronic system, integrated onto the surface or in the volume of a thermoplastic matrix. The electronic system comprises at least one piezoelectric transducer and means for transmitting an electrical signal. The piezoelectric transducer comprising a piezoelectric polymer essentially consisting of, or consisting of, repeating units derived from vinylidene fluoride (VDF) and vinylidene trifluoride (TrFE), the molar proportion of the unit derived from TrFE being from 15% to 50% relative to the total number of moles of the units derived from VDF and TrFE.

According to certain embodiments, the thermoplastic matrix may be a (meth)acrylic matrix, preferentially comprising a methyl methacrylate (MMA) homopolymer, or a copolymer comprising at least 70% by weight of MMA, or a mixture thereof.

According to certain embodiments, the piezoelectric polymer may have a molar proportion of repeating unit derived from TrFE of from 16% to 35%, preferentially from 17% to 32%, more preferably from 18% to 27%, and extremely preferably from 19% to 22%, relative to the total number of moles of units derived from VDF and TrFE.

According to certain embodiments, the piezoelectric polymer may notably have a Curie temperature strictly greater than 80° C., or greater than or equal to 85° C., or greater than or equal to 90° C., or greater than or equal to 95° C., or greater than or equal to 100° C., or greater than or equal to 105° C., or greater than or equal to 110° C., or greater than or equal to 115° C., or greater than or equal to 120° C., or greater than or equal to 125° C., or greater than or equal to 130° C., or greater than or equal to 135° C., or greater than or equal to 140° C., or even greater than or equal to 145° C.

According to a first embodiment, the transducer, or the plurality of transducers, comprises a piezoelectric polymer film.

According to a second embodiment, the transducer, or the plurality of transducers, is a fiber comprising: an inner conductive core constituting a first electrode, an intermediate coating comprising said at least one piezoelectric polymer adhering to said conductive core, and an outer conductive coating constituting a second electrode.

According to a third embodiment, the transducer, or the plurality of transducers, and/or the electrical signal transmission means, may be obtained by electronic substrate printing methods.

The printing method is preferentially chosen from: spin coating, spray coating, coating notably with a bar or a film spreader (bar coating), slot-die coating, dip coating, roll-to-roll printing, screen printing, flexographic printing, lithographic printing, electrospinning or inkjet printing.

According to certain embodiments, the piezoelectric polymer of the transducer has a thickness of from 1 micron to 50 microns, preferentially from 2 microns to microns, and extremely preferably from 5 to 15 microns.

According to certain embodiments, the article according to the invention comprises a plurality of piezoelectric transducers forming an array.

According to certain embodiments, the electronic system is integrated into the thermoplastic matrix via an operating process whose temperature does not exceed the Curie temperature of the piezoelectric polymer.

According to certain embodiments, the article according to the invention comprises a reinforcing material. The reinforcing material is preferentially a material consisting of long fibers, notably glass fibers or carbon fibers.

According to certain embodiments, the electronic system is integrated into the thermoplastic matrix via an in-situ polymerization process.

According to certain embodiments, the instrumented article may particularly be a structural element or a composite multilayer structure for distributing or storing hydrogen, a wind turbine element, notably a wind turbine blade, a rebar for concrete, or a structural element for a battery pack.

According to certain embodiments, the article according to the invention is suitable and intended for recycling.

According to a second aspect, the invention relates to the use of an electronic system for monitoring the progress of a process (Process Monitoring) for integrating said electronic system into a thermoplastic matrix, the electronic system and the thermoplastic matrix being intended to form a composite article according to the invention.

According to a third aspect, the invention relates to the use of the article according to the invention for measuring and/or monitoring properties of said article, notably for Structural Health Monitoring.

The inventors thus developed an instrumented article, in which the transducer(s) are particularly robust, notably under constrained temperature and pressure conditions, have good sensitivity even under constrained conditions, and are readily integrable and in a variety of forms, into a thermoplastic matrix. The instrumented article comprising thermoplastic polymers is also advantageously suitable and intended for recycling.

### LIST OF FIGURES

The invention will be understood more clearly in the light of the following figures and the following detailed description of nonlimiting embodiments of the invention:

FIG. 1 schematically represents a P(VDF-TrFE) film-based transducer according to the invention.

FIG. 2 schematically represents a transducer in the form of a piezoelectric fiber.

FIG. 3 schematically represents a fiber network according to FIG. 2.

FIG. 4 schematically represents an array of transducers printed on a substrate.

FIG. 5 schematically represents a mold for an infusion process.

FIG. 6 schematically represents a thermoplastic composite laminate with integrated sensor arrays, notably arrays according to FIG. 4, which can be manufactured using an impregnation process as shown in FIG. 5.

### DETAILED DESCRIPTION OF THE INVENTION

The invention relates to a composite article comprising at least one electronic system, integrated onto the surface or in the volume of a thermoplastic matrix. The term “composite article” as used herein means in the most general sense a multi-component material, and notably as used herein at least one electronic system and a thermoplastic matrix. The thermoplastic matrix may itself, in certain embodiments, be the basis of a thermoplastic composite, i.e. comprising another component, usually a reinforcing material.

The term “integrated onto the surface” means that the electronic system, at least the piezoelectric transducer, is attached directly to the surface of the article. According to certain embodiments, the electronic system, at least the piezoelectric transducer, is attached to the surface of the article by means of a suitable adhesive. Although part of the invention, this is not a preferred embodiment, since the acoustic coupling with the sensor is generally relatively weak. According to certain embodiments, the electronic system may be soldered to the surface of the article.

The term “integrated in the volume” means that the electronic system, at least the piezoelectric transducer, is within the volume of the article. It may be fixed or embedded in the volume of the article. Incorporating the transducer directly into the volume of the article rather than onto the surface offers certain advantages, such as better acoustic coupling.

The term “thermoplastic” or “thermoplastic polymer” denotes a material that is generally solid at room temperature, which may be semicrystalline or amorphous, and which softens during an increase in temperature, in particular after passing its glass transition temperature (Tg) and flows at higher temperature when it is amorphous, or which may exhibit sharp melting on passing its “melting” point (Tm) when it is semicrystalline, and which becomes solid again during a reduction in temperature below its crystallization temperature (for a semicrystalline material) and below its glass transition temperature (for an amorphous material).

Tg and Tm are determined by differential scanning calorimetry (DSC) according to the standards ISO11357-2:2013 and ISO11357-3:2013, respectively.

Unlike thermosetting polymers, which are unmeltable and non-transformable, thermoplastic polymers can be recycled.

The thermoplastic polymers used for forming the thermoplastic matrix may be chosen from:
polymers and copolymers of the acrylic family, such as polyacrylates or polymethacrylates, and more particularly polymethyl methacrylate (PMMA) or derivatives thereof,
polymers and copolymers of the family of aliphatic or cycloaliphatic polyamides (PAs) or semiaromatic PAs (also referred to as polyphthalamides (PPAs)),
polyureas, in particular aromatic polyureas,
polymers and copolymers of the polyaryl ether ketone (PAEK) family, such as polyether ether ketone (PEEK), or polyaryl ether ketone ketones (PAEKK), such as polyether ketone ketone (PEKK), or derivatives thereof,
   aromatic polyether imides (PEls),
   polyaryl sulfides, in particular polyphenylene sulfides (PPSs),
   polyaryl sulfones, in particular polyphenylene sulfones (PPSUs),
   polyolefins, in particular polypropylene (PP);
   polylactic acid (PLA),
   polyvinyl alcohol (PVA),
   fluoropolymers, in particular polyvinylidene fluoride (PVDF) or polytetrafluoroethylene (PTFE) or polychlorotrifluoroethylene (PCTFE), and mixtures thereof.

In preferred embodiments, the thermoplastic matrix may notably be a (meth)acrylic matrix, and notably PMMA. Such thermoplastic matrices are particularly advantageous. Indeed, it is known practice to form such matrices, notably to form thermoplastic composites incorporating a fibrous material, at “low” temperatures, i.e. notably at temperatures less than or equal to 145° C., or less than or equal to 135° C., or less than or equal to 130° C., or less than or equal to 120° C., or less than or equal to 110° C., or less than or equal to 100° C., or less than or equal to 90° C. Such matrices are also known to be recyclable.

In the present context, the term “(meth)acrylic” refers to any type of acrylic or methacrylic monomer.

In the present context, the term “PMMA” denotes a methyl methacrylate (MMA) homopolymer or copolymer or mixtures thereof. According to one embodiment, the methyl methacrylate (MMA) homo- or copolymer comprises at least 70%, preferably at least 80%, advantageously at least 90% and more advantageously at least 95% by weight of methyl methacrylate.

According to certain embodiments, the PMMA may be a blend of at least one homopolymer and at least one MMA copolymer.

According to certain embodiments, the PMMA may be a blend of at least two homopolymers.

According to certain embodiments, the PMMA may be a blend of two MMA copolymers having different average molecular weights.

According to certain embodiments, the PMMA may be a blend of at least two MMA copolymers having a different monomer composition.

The methyl methacrylate (MMA) copolymer may comprise from 70% to 99.7% by weight of methyl methacrylate and from 0.3% to 30% by weight of at least one other monomer containing at least one ethylenic unsaturation that can copolymerize with methyl methacrylate. These other monomers are well known and mention may notably be made of acrylic and methacrylic acids and alkyl(meth)acrylates in which the alkyl group contains from 1 to 12 carbon atoms. As examples, mention may be made of methyl acrylate and ethyl, butyl or 2-ethylhexyl (meth)acrylate. Preferably, the comonomer is an alkyl acrylate in which the alkyl group contains from 1 to 4 carbon atoms.

According to preferred embodiments, the methyl methacrylate (MMA) copolymer may comprise from 80% to 99.9%, advantageously from 90% to 99.9% and more advantageously from 90% to 99.9% by weight of methyl methacrylate and from 0.1% to 20%, advantageously from 0.1% to 10% and more advantageously from 0.1% to 10% by weight of at least one monomer, containing at least one ethylenic unsaturation, which may be copolymerized with the methyl methacrylate. Preferably, the comonomer is chosen from methyl acrylate and ethyl acrylate, and mixtures thereof.

The weight-average molecular mass of the thermoplastic matrix used for manufacturing an article is generally high. The weight-average molecular mass is preferentially greater than 50 000 g/mol, and even more preferably greater than 100 000 g/mol, as measured by gel permeation chromatography.

The piezoelectric polymer of said at least one transducer consists essentially of, or consists of, repeating units derived from vinylidene fluoride (VDF) and vinylidene trifluoride (TrFE), the molar proportion of the unit derived from TrFE being from 15% to 50% relative to the total number of moles of the units derived from VDF and TrFE.

The piezoelectric copolymer is a thermoplastic. It may thus be readily recycled and is not a source of heavy metals, as are piezoelectric ceramics.

The polymer crystallizes almost exclusively in the beta phase, and thus has excellent ferroelectric properties. On the other hand, below a 15% molar proportion of TrFE-based units or above a 50% molar proportion of TrFE-based units, the crystalline phase crystallizes much less well in the beta (ferroelectric) form.

According to preferred embodiments, the piezoelectric polymer has a molar proportion of TrFE-based repeating units of from 16% to 35%, preferentially from 17% to 32%, more preferably from 18% to 27%, and extremely preferably from 19% to 22%, relative to the total number of moles of units derived from VDF and TrFE.

The piezoelectric polymer may notably have a molar proportion of TrFE-based repeating units of about 20% relative to the total number of moles of units derived from VDF and TrFE.

In the abovementioned ranges of values, advantageously in the preferred ranges of values, the piezoelectric polymer used in the article according to the invention has at least some of the following features:
a wide bandwidth (10 Hz-50 MHz), notably in comparison with sensors based on piezoelectric ceramics;
a high voltage constant g33, through a low relative permittivity εᵣ, notably in comparison with piezoelectric ceramics;
relative flexibility, allowing integration on curved surfaces and/or surfaces subject to high mechanical stress, which may be difficult to achieve with piezoelectric ceramics;
low acoustic impedance compared with piezoelectric ceramics, close to that of polymer materials: this makes it possible to dispense with the use of an acoustic matching layer at the transducer/thermoplastic matrix interface, which is generally necessary for piezoelectric ceramics;
a non-resonant property, i.e. the signals are received with more or less equal sensitivity over a wide range of frequencies, unlike piezoelectric ceramic sensors which are generally of the resonant type with high sensitivity in their resonant bandwidths;
high thermal stability, notably compared with that of polarized PVDF, which loses its electroactive properties above 80° C.,
high sensitivity, notably compared with polarized PVDF, through a high electro-acoustic coupling coefficient kt.

The piezoelectric copolymer in the abovementioned VDF and TrFE ratio ranges is moreover soluble in a wider variety of solvents than is PVDF, allowing it to be formulated as an ink and readily used in electronic printing techniques with ease and flexibility.

According to certain embodiments, the piezoelectric polymer comprises, in addition to the repeating units derived from VDF and TrFE, up to 1 mol % of at least one repeating unit derived from a monomer other than VDF and TrFE, the other monomer being chosen from the list consisting of:
a vinylphosphonic acid dialkyl ester, notably vinylphosphonic acid dimethyl ester or vinylphosphonic acid;
an acrylic or methacrylic monomer, notably acrylic acid, methacrylic acid, (2-trifluoromethyl)acrylic acid, hydroxyethyl acrylate, hydroxyethyl methacrylate, hydroxypropyl acrylate, hydroxypropyl methacrylate, hydroxyethylhexyl acrylate or hydroxyethylhexyl methacrylate,
another fluoro monomer, notably vinyl fluoride (VF), tetrafluoroethylene (TFE), a chlorofluoroethylene (CFE), a chlorodifluoroethylene, chlorotrifluoroethylene (CTFE), dichlorodifluoroethylene, a trichlorofluoroethylene, hexafluoropropylene (HFP), a trifluoropropene, a tetrafluoropropene, a chlorotrifluoropropene, hexafluoroisobutylene, perfluorobutylethylene, a pentafluoropropene, a perfluoro ether, notably a perfluoroalkyl vinyl ether; and a mixture thereof.

According to certain embodiments, the piezoelectric polymer consists of repeating units derived from VDF and TrFE.

The Curie temperature corresponds to a ferroelectric->paraelectric (FE->PE) crystal structure transition, known as the Curie transition, corresponding to abrupt depolarization of the macroscopic ferroelectric domains. It may be determined, for example, by differential scanning calorimetry (DSC), as the temperature of the maximum of the endotherm corresponding to this transition, during the first or second heating, preferentially during the second heating, at 10° C./min, or by dielectric spectroscopy, as the temperature corresponding to the maximum of the dielectric permittivity peak during heating at 10° C./min at a frequency of 1 kHz.

The Curie temperature of the piezoelectric polymer may be adjusted as a function of the polymer's VDF and TrFE composition: the higher the proportion of vinylidene fluoride, the higher the Curie temperature. For example, the Curie temperature of P(VDF-TrFE) (80:20) (mol:mol) is known to be: 137° C. Thus, a transducer comprising P(VDF-TrFE) (80:20) (mol:mol), may be used in the polarized state in the article according to the invention and/or may be used at an operating temperature of up to about 135° C. By way of comparison, the Curie temperature of P(VDF-TrFE) (84:16) (mol:mol) is: 150° C. whereas the Curie temperature of P(VDF-TrFE) (65:35) (mol:mol) is: 84° C. As required, notably depending on the operating conditions under which the article is used, the composition of the piezoelectric polymer may be adjusted so that its Curie temperature is strictly greater than 80° C., or greater than or equal to 85° C., or greater than or equal to 90° C., or greater than or equal to 95° C., or greater than or equal to 100° C., or greater than or equal to 105° C., or greater than or equal to 110° C., or greater than or equal to 115° C., or greater than or equal to 120° C., or greater than or equal to 125° C., or greater than or equal to 130° C., or greater than or equal to 135° C., or greater than or equal to 140° C., or even greater than or equal to 145° C.

According to preferred embodiments, the thermoplastic matrix is chosen so that the temperature at which the matrix is formed to incorporate the transducer is lower than the Curie temperature of the piezoelectric polymer. In these embodiments, the transducer may be integrated already polarized, may be used, where appropriate, to control the process of integrating the transducer or transducer array within the thermoplastic matrix, and will retain its polarization once the article has been formed. As already described, the thermoplastic matrix may notably be a (meth)acrylic matrix, and notably PMMA.

According to certain embodiments, the piezoelectric polymer has a mass-average molar mass of from 100 000 g/mol to 2 000 000 g/mol, preferably from 300 000 g/mol to 1 500 000 g/mol, and extremely preferably from 400 000 to 700 000 g/mol.

According to certain embodiments, the piezoelectric polymer is a polymer with a homogeneous structure, preferentially a random copolymer.

According to certain embodiments, the VDF-based units in the piezoelectric polymer are derived, at least partly, from biobased VDF.

The electronic system suitable for structural health monitoring comprises at least one transducer and electrical transmission means. A transducer is formed by at least the piezoelectric polymer interposed between two electrodes.

Three modes of transducer use may be considered:
acoustic emission;
electromechanical impedance; and
ultrasonic emission.

The transducer may be used as a receiver, i.e. passively, or as an actuator, i.e. actively. The function of the transducer is not predetermined a priori, and it is thus conceivable to operate it at certain times as a sensor and at others as an actuator. According to certain embodiments, the transducer is an “interdigital” transducer, i.e. the electrodes are comb-shaped and intersect.

The electronic system according to the invention advantageously comprises a plurality of transducers, forming an array of more or less interconnected transducers. More precisely, certain transducers may be placed in electrical communication with each other, sharing the same electrical transmission path. Such arrays, integrated onto the surface and/or in volume of the article, are capable of detecting and/or transmitting mechanical waves within the structure of the composite article so as to detect the presence of damage or to probe the structure of the article.

Piezoelectric sensors may, for example, detect and measure wave propagation within the article (propagation speed, wave intensities, etc.). The measured wave may, in certain situations, have been generated by an actuator producing a mechanical wave of low intensity and known frequency in the structure (active detection). In other situations, the measured wave may have been generated by an impact, or an internal source such as a crack in the structure (passive detection).

Piezoelectric sensors may, for example, also measure deformations, variations in stress or temperature, etc.

The electrical transmission means allow an electrical signal to be conducted to and from each of the transducers. They may consist, for example, of electrical wires or, alternatively, of conductive tracks printed on a substrate (see the electronic printing techniques below).

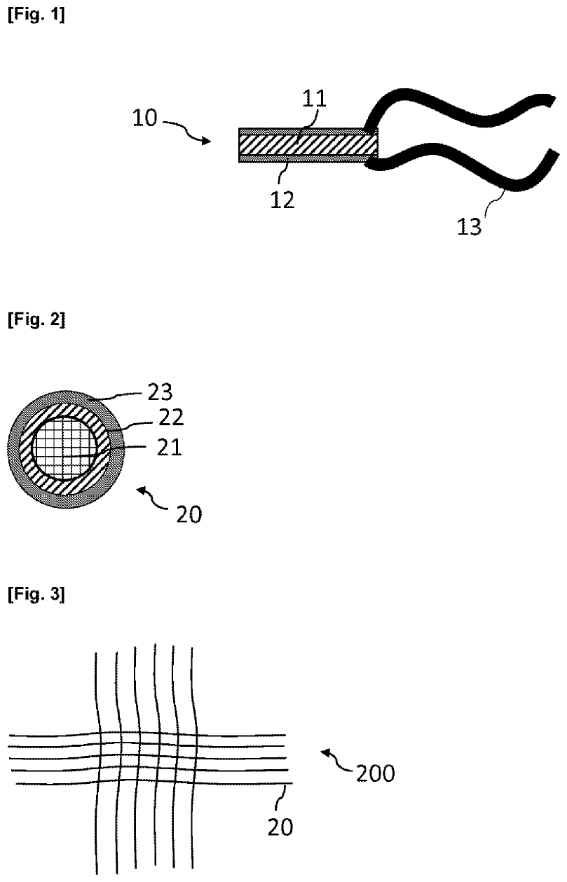

According to a first embodiment, with reference to FIG. 1, transducer 10 may be a piezoelectric polymer film 11 interposed between two electrodes 12, such as the transducers used for the COPV or for the wind turbine prototype described in the prior art. In general, the surface area occupied by such a transducer is of the order of 0.1 to 100 cm². Electrical cables 13 welded to the electrodes ensure transmission of the electrical signal. Although part of the invention, this is not a preferred embodiment due to the bulkiness of the electrical cables. This embodiment is even less preferred when the transducer, or transducer array, is integrated into the volume of the article, due to the invasive nature of the electrical cables. Nevertheless, this embodiment is still conceivable, notably when the transducer(s) are arranged on the surface of the article.

It may also be envisaged that the transducer has the structure of the first embodiment (film and electrodes) in the form of an elongated ribbon, which is closer to the second embodiment presented below.

According to a second embodiment, the transducer may be a continuous piezoelectric fiber. With reference to FIG. 2 representing a cross section, the fiber 20 comprises a metal core 21 constituting a first electrode. The metal core may, for example, be made of copper, platinum, stainless steel, molybdenum, or an alloy thereof. The fiber comprises an intermediate coating 22 comprising said piezoelectric polymer adhering to the conductive core. Finally, the fiber comprises a conductive coating 23 at least partly covering the intermediate coating and constituting a second electrode. The fiber may have an average diameter ranging from 500 micrometers to 5 micrometers, and preferably from 400 micrometers to micrometers.

A process for manufacturing such fibers was notably described in detail in WO 2020/128230.

Although the fiber represented in FIG. 2 is a continuous fiber of circular cross section, embodiments in which the fiber has a different cross-sectional shape, notably rectangular, may also be envisaged.

In certain embodiments, several fibers may be assembled together to form a fiber network. The piezoelectric fiber network may, for example, form a two-dimensional grid, such as that shown diagrammatically in FIG. 3, or even a three-dimensional grid.

The fiber, or fiber network, may be associated with a fibrous reinforcing material, as will be seen hereinbelow, of one-dimensional, or two-dimensional, or even three-dimensional form. The fiber or fiber network may notably be integrated into a mat of continuous filaments, fabrics, felts or nonwovens, which may be in the form of strips, mats, braids or bunches of fibrous reinforcing materials.

According to certain embodiments, a piezoelectric fiber or, more often, a network of piezoelectric fibers may be included in a woven or nonwoven fiber, for example within a reinforcing material. The piezoelectric fiber network may, for example, form a two-dimensional grid, such as that shown diagrammatically in FIG. 3, or even a three-dimensional grid.

According to a third, preferred embodiment, the transducer and/or the electrical transmission means may be obtained via printed electronic techniques, i.e. by applying compositions that are suitable and intended for forming the transducer constituents on a thermoplastic substrate, notably by spreading by discrete or continuous means. This embodiment is particularly advantageous as it allows the greatest freedom of form and design.

With reference to FIG. 4, a circuit 300 comprises a plurality of transducers 30 forming an array, connected independently, or in series, or in parallel by conductive tracks 32, 33, printed on a substrate 31. Although the substrate is represented here as a continuous film, according to certain embodiments, certain zones supporting neither the transducers nor the electrical tracks may be cut out, for example by laser, so as to limit the space requirement and the invasive nature of the circuit in the volume of the article.

The circuit represented in FIG. 4 does not necessarily represent a real case, but allows different arrangements of transducers to be exemplified within a transducer array.

The deposition may notably be performed by spin coating, spray coating, coating notably with a bar or a film spreader (bar coating), slot-die coating, dip coating, roll-to-roll printing, screen printing, flexographic printing, lithographic printing, electrospinning or inkjet printing.

According to certain embodiments, the substrate may be of the same chemical nature as the thermoplastic matrix. For example, in the case where the thermoplastic matrix is a PMMA, the substrate may also be a PMMA.

Typical substrates for piezoelectric polymer transducers notably include polyethylene terephthalate (PET), polyethylene naphthalate (PEN), paper, PMMA, polycarbonate (PC) and polyamides.

In contrast to PVDF, the piezoelectric copolymer in the VDF and TrFE ratio ranges according to the invention may be used with a wide variety of liquid vehicles. The liquid vehicle may be chosen, in a nonlimiting manner, from esters such as ethyl acetate, propyl acetate, butyl acetate, isobutyl propionate, propylene glycol monomethyl ether, methyl lactate, ethyl lactate and gamma-butyrolactone; alkyl phosphates such as triethyl phosphate; alkyl carbonates such as dimethyl carbonate; ketones such as acetone, acetylacetone, methyl isobutyl ketone, 2-butanone, 2-pentanone, 2-heptanone, 3-heptanone, cyclopentanone and cyclohexanone; amides such as dimethylformamide (DMF) or dimethylacetamide (DMAc); sulfur-based solvents such as dimethyl sulfoxide (DMSO); halogenated solvents such as chloroform, and haloalkanes; and mixtures thereof. It is preferred in this invention to use 2-butanone, cyclohexanone, dimethyl sulfoxide, propylene glycol monomethyl ether, triethyl phosphate, dimethylacetamide, and mixtures thereof.

Electrode deposition may be performed by evaporation or sputtering or printing, of metal, indium-tin oxide, a conductive polymer layer, silver-based conductive ink, silver nanowires, conductive polymers such as PEDOT:PSS, or graphene. Although not represented on the schematic diagram of the three embodiments discussed above (cf. FIG. 1, FIG. 2 and FIG. 4), it is conceivable to at least partly cover the transducer(s), and where appropriate the conductive tracks, with a protective layer of an insulating material. This notably allows, where necessary, protection against any surrounding pollutants, notably to avoid electrical short-circuits and to improve the operational stability and reliability. Preferably, the insulating material is a thermoplastic. According to certain embodiments, the insulating material may be of the same chemical nature as the thermoplastic matrix. The insulating material may notably be PMMA.

To be used as a transducer, the piezoelectric polymer must be polarized by methods known per se: by contact polarization by applying a DC or AC voltage, or without contact using the Corona effect. Polarization may be performed in a number of ways, either during manufacture of the transducer itself, or once the various transducer components have been assembled.

According to certain embodiments, the transducer, or transducer array, is polarized before being integrated into the thermoplastic matrix.

According to certain embodiments, the transducer, or transducer array, is polarized after having been integrated into the thermoplastic matrix.

It may also be envisaged to polarize the transducers before their integration into the thermoplastic matrix in order to check their integrity, and then to polarize them again once the transducer(s) have been integrated if said transducer(s) have been subjected to temperature conditions that have caused their depolarization. The advantage of the piezoelectric copolymer used in transducers according to the invention is that it may be repolarized after depolarization due to thermal treatment, unlike PVDF.

According to advantageous embodiments, the transducer, or transducer array, is polarized before integration into the thermoplastic matrix and remains functional after having been integrated into the thermoplastic matrix. This is notably possible if the temperature during the integration process does not exceed the Curie temperature value.

The article according to the invention may, at least according to certain embodiments, comprise a reinforcing material, notably a fibrous material. The fibrous material may have different shapes (one-dimensional, two-dimensional or three-dimensional). The fibrous material generally comprises an assembly of one or more fibers. It may be in the form of fibers, unidirectional bunches or a mat of continuous filaments, woven fabrics, felts or nonwovens, which may be in the form of strips, mats, braids, bunches or pieces.

The one-dimensional form corresponds to linear long fibers. The fibers may be discontinuous or continuous. The fibers may be arranged randomly or parallel to each other, in the form of a continuous filament. A fiber is defined by its length ratio, which is the ratio between the length and the diameter of the fiber. The fibers generally used are long fibers or continuous fibers. The fibers have a length ratio of at least 1000, preferably at least 1500, more preferably at least 2000, advantageously at least 3000, more advantageously at least 5000, even more advantageously at least 6000, even more advantageously at least 7500 and most preferably at least 10 000.

The two-dimensional form corresponds to nonwoven or woven fibrous mats, or reinforcements, or bundles of fibers, which may also be braided. Even if the two-dimensional form has a certain thickness and consequently in principle a third dimension, it is considered herein to be two-dimensional.

The three-dimensional form corresponds, for example, to nonwoven fibrous mats or reinforcements or stacked or folded bundles of fibers or mixtures thereof, an assembly of the two-dimensional form in the third dimension.

The origins of the fibrous material may be natural or synthetic. Natural materials that may be mentioned include plant fibers, wood fibers, animal fibers or mineral fibers.

Natural fibers are, for example, sisal, jute, hemp, flax, cotton, coconut fibers, and banana fibers. Animal fibers are, for example, wool or fur.

Synthetic materials that may be mentioned include polymeric fibers chosen from fibers of thermosetting polymers, of thermoplastic polymers or mixtures thereof.

The polymeric fibers may consist of polyamide (aliphatic or aromatic), polyester, polyvinyl alcohol, polyolefins, polyurethanes, polyvinyl chloride, polyethylene, unsaturated polyesters, epoxy resins and vinyl esters.

The mineral fibers may also be chosen from glass fibers, in particular of type E, R or S2, carbon fibers, boron fibers or silica fibers.

Preferably, the fibrous material is chosen from mineral fibers. More preferably, the fibrous material is chosen from glass fibers or carbon fibers.

The fibers of the fibrous material advantageously have a diameter of between 0.005 μm and 100 μm, preferably between 1 μm and 50 μm, more preferably between 5 μm and 30 μm and advantageously between 10 μm and 25 μm.

Preferably, the fibers of the fibrous material of the present invention are chosen from continuous fibers (meaning that the length ratio does not necessarily apply as for long fibers) for the one-dimensional form, or from long or continuous fibers for the two-dimensional or three-dimensional form of the fibrous material.

According to certain embodiments, the composite article comprises a fibrous material and is obtained by impregnation. The term “impregnation” as used denotes the penetration of monomeric, oligomeric or polymeric liquids or mixtures thereof into a fiber assembly. The electronic system may thus be arranged at pre-established locations with optimum coupling within the volume of the article during the impregnation step. This embodiment is illustrated hereinbelow with a PMMA matrix.

According to certain embodiments, the composite article may comprise fillers other than the reinforcing material and/or functional additives. The functional additives may notably include one or more surfactants, UV stabilizers, thermal stabilizers, light stabilizers, impact modifiers, plasticizers, expanders and/or biocidel agents, thermally and/or electrically conductive particles, colorants, fire retardants, flame retardants, etc. The fillers may notably be mineral fillers such as alumina, silica, calcium carbonate, titanium dioxide, glass beads, carbon black, graphite, graphene and carbon nanotubes.

### Use in SHM

Piezoelectric sensors may be used for identifying shock and/or damage mechanisms. It is considered that there are four main damage mechanisms that can be identified in thermoplastic composites, i.e. composites comprising a thermoplastic matrix and a reinforcing material, by their acoustic emission “signature”: (i) cracking of the thermoplastic matrix, (ii) interfacial debonding, (iii) fiber/matrix friction, fiber pull-out and (iv) fiber breakage. Of these four mechanisms, the first relates to thermoplastics in general, whether or not comprising a reinforcing material.

Most of this damage occurs below the upper surfaces and is barely visible. They can severely degrade the performance of composites and need to be identified in time to avoid catastrophic structural failure.

Composite failure modes generate acoustic waves in specific frequency ranges: matrix micro-cracking (50-170 kHz), fiber pull-out (170-220 kHz), decoupling/delamination (220-300 kHz) and fiber breakage (300 to 500 kHz). Each type of damage may be classified according to the dominant frequency band extracted from the piezoelectric sensor signals.

Alternatively and/or additionally, acoustic waves may also be generated by active transducers so as to provide periodic information on the state of the composite structure.

Finally, piezoelectric sensors may also measure deformations, stress variations, temperature variations, etc.

An SHM system generally comprises signal acquisition and processing means, for instance an attenuation circuit to manage the amplitudes of the electrical signals generated by the sensors, filtering elements to isolate different range frequencies from the electrical signals, an analyzer to analyze the filtered signals at different frequencies, a microprocessor, etc., so as to be able to acquire and analyze the electrical signal transmitted by the sensors. According to certain embodiments, at least some of these acquisition and/or processing elements may form part of the electronic system integrated into the composite article. According to certain embodiments, some of these elements do not form part of the integrated electronic system and are external to the composite article.

### Articles

The article according to the invention may be used in many applications. It may notably be used in the transport sector (motor vehicle part, boat part, train part, aircraft or helicopter part, spacecraft or rocket part, etc.), in the energy sector (battery pack part, wind turbine part, photovoltaic module part, etc.), a construction or building part (rebar), an electrical or electronic apparatus part (telephone part, computer part, etc.).

The composite articles according to the invention may notably be structural elements or multilayer composite structures for hydrogen distribution or storage, structural elements for wind turbines, such as wind turbine blades, rebars for concrete, or structural elements or structures for battery packs.

The term “multilayer structure” means, for example, a tank, pipe or tube comprising or consisting of several layers, notably two layers. The electronic system may be integrated into the volume or onto the surface of one of the layers. It may notably be used for measuring temperature variations, stress variations and the state of the structure during various dihydrogen charges and discharges. The term “rebar” means a reinforcing bar that is used as a tensioning device in reinforced concrete and reinforced masonry structures to reinforce and support the concrete under tension. Given the shape of such bars, the electronic system must have an elongated form, and may notably comprise piezoelectric fibers or printed transducer tabs. A process for manufacturing such bars from PMMA composites is disclosed in FR3087203. The electronic system may notably allow the stresses within the rebars and their fatigue state over time to be evaluated.

The article according to the invention may also be a structural part for a wind turbine, notably a wind turbine blade. A sensor network may notably be deployed over a long length. The electronic system is advantageously integrated into the volume so as not to interfere with the aerodynamics of the blade.

The article according to the invention may also be used in a battery pack to allow identification of anomalies in certain cells (excessive temperatures, deterioration, etc.).

### Process for Manufacturing a Composite Article According to the Invention

The process comprises:
a step of providing an electronic system as described in the preceding section;
a step of forming the thermoplastic matrix in such a way that the electronic system, and optionally a reinforcing material or other fillers, are integrated therein.

Standard processes for forming thermoplastic materials, and where appropriate thermoplastic composites, may generally be used.

Advantageously, the processing temperature of the thermoplastic matrix does not exceed the Curie temperature of the piezoelectric polymer. The processing temperature of the thermoplastic matrix may thus be less than or equal to 145° C., or less than or equal to 135° C., or less than or equal to 130° C., or less than or equal to 120° C., or less than or equal to 110° C., or less than or equal to 100° C., or less than or equal to 90° C.

This allows integration of the electronic system comprising already polarized transducer(s). Although possible and conceivable, this makes it possible to avoid polarizing the transducers once they have been integrated into the matrix.

Integrating the electronic system with already polarized transducers also allows them to be used during the integration process to control various parameters of the integration process itself (temperature, curing pressure).

According to a particular embodiment, detailed below for a fibrous composite based on a thermoplastic (meth)acrylic matrix, the thermoplastic matrix of the article may be obtained by in-situ polymerization of monomers and/or prepolymers.

In the present context, the term “polymerization” denotes the process of converting a monomer or a mixture of monomers into a polymer.

In the present context, the term “in-situ polymerization” means that the final polymerization of the thermoplastic matrix takes place around the electronic system, and in the case of the embodiment developed herein around the fibrous reinforcing material, so as to directly produce the composite article.

In the present context, the term “monomer” denotes a molecule which can undergo a polymerization.

In the present context, the term “prepolymer” denotes a polymer or oligomer whose molecules are capable of undergoing further polymerization via reactive groups.

As used hereinbelow, the term “initiator” denotes a chemical species that forms a compound or an intermediate compound which starts the polymerization of a monomer, which is capable of successfully linking a large number of other monomers into a polymer compound.

As used hereinbelow, the term “impregnation” denotes the penetration of monomeric, oligomeric or polymeric liquids or mixtures thereof into a fiber assembly.

The thermoplastic (meth)acrylic matrix may be polymerized using a liquid composition LC1, or “(meth)acrylic syrup”, comprising a (meth)acrylic polymer (P1), a (meth)acrylic monomer (M1) or a mixture of (meth)acrylic monomers (M1) and (M1+x), and at least one initiator (Init).

The dynamic viscosity of the liquid composition LC1 or of the (meth)acrylic syrup may be in a range from 10 mPa*s to 10 000 mPa*s, preferably from 20 mPa*s to 7000 mPa*s, advantageously from 20 mPa*s to 5000 mPa*s, more advantageously from 20 mPa*s to 2000 mPa*s and even more advantageously from 20 mPa*s to 1000 mPa*s. The viscosity of the syrup can be readily measured with a rheometer or a viscometer. The dynamic viscosity is measured at 25° C. If the liquid (meth)acrylic syrup has Newtonian behavior, meaning no shear thinning takes place, the dynamic viscosity is independent of the shear in a rheometer or of the speed of the spindle in a viscometer. If the liquid composition LC1 shows non-Newtonian behavior, i.e. meaning that shear-thinning takes place, the dynamic viscosity is measured at a shear rate of 1 s⁻¹ at 25° C.

The liquid composition LC1 or (meth)acrylic syrup, for impregnating the fibrous material, may in particular comprise a (meth)acrylic monomer (M1), a (meth)acrylic polymer (P1) and at least one initiator (Init). Once polymerized, the (meth)acrylic monomer (M1) is converted into the (meth)acrylic polymer (P2) comprising the monomer units of (meth)acrylic monomer (M1).

As regards the (meth)acrylic polymer (P1), mention may be made of polyalkyl methacrylates or polyalkyl acrylates. According to a preferred embodiment, the (meth)acrylic polymer (P1) is poly(methyl methacrylate) (PMMA).

According to certain embodiments, the PMMA may be a mixture of at least one homopolymer and at least one copolymer of MMA, or a mixture of at least two homopolymers or two copolymers of MMA with a different average molecular weight, or a mixture of at least two copolymers of MMA with a different monomer composition.

The methyl methacrylate (MMA) copolymer comprises from 70% to 99.7% by weight of methyl methacrylate and from 0.3% to 30% by weight of at least one monomer containing at least one ethylenic unsaturation that may be copolymerized with methyl methacrylate.

These monomers are well known and mention may be made notably of acrylic and methacrylic acids and alkyl(meth)acrylates in which the alkyl group contains from 1 to 12 carbon atoms. As examples, mention may be made of methyl acrylate and ethyl, butyl or 2-ethylhexyl (meth)acrylate. Preferably, the comonomer is an alkyl acrylate in which the alkyl group contains from 1 to 4 carbon atoms.

According to a first preferred embodiment, the methyl methacrylate (MMA) copolymer may comprise from 80% to 99.9%, advantageously from 90% to 99.9% and more advantageously from 90% to 99.9% by weight of methyl methacrylate and from 0.1% to 20%, advantageously from 0.1% to 10% and more advantageously from 0.1% to 10% by weight of at least one monomer containing at least one ethylenic unsaturation, which may be copolymerized with methyl methacrylate. Preferably, the comonomer is chosen from methyl acrylate and ethyl acrylate, and mixtures thereof.

The weight-average molecular mass of the (meth)acrylic polymer (P1) is advantageously high, meaning greater than 50 000 g/mol and preferably greater than 100 000 g/mol.

The weight-average molecular weight may be measured by exclusion chromatography (SEC).

The (meth)acrylic polymer (P1) is fully soluble in the (meth)acrylic monomer (M1) or in the mixture of (meth)acrylic monomers. This enables the viscosity of the (meth)acrylic monomer (M1) or the mixture of (meth)acrylic monomers to be increased. The solution obtained is liquid composition generally called a “syrup” or a “prepolymer”. The dynamic viscosity value of the liquid (meth)acrylic syrup may be between 10 mPa·s and 10 000 mPa·s. The viscosity of the syrup can be readily measured with a rheometer or a viscometer. The dynamic viscosity is measured at 25° C. Advantageously, the liquid (meth)acrylic composition, or syrup, contains no deliberately added additional solvent.

As regards the (meth)acrylic monomer (M1), the monomer may be chosen from acrylic acid, methacrylic acid, alkyl acrylic monomers, alkyl methacrylic monomers, hydroxyalkyl acrylic monomers and hydroxyalkyl methacrylic monomers, and mixtures thereof.

Preferably, the (meth)acrylic monomer (M1) may be chosen from acrylic acid, methacrylic acid, hydroxyalkyl acrylic monomers, hydroxyalkyl methacrylic monomers, alkyl acrylic monomers, alkyl methacrylic monomers and mixtures thereof, the alkyl group containing from 1 to 22 linear, branched or cyclic carbons; the alkyl group preferably containing from 1 to 12 linear, branched or cyclic carbons.

Advantageously, the (meth)acrylic monomer (M1) may be chosen from methyl methacrylate, ethyl methacrylate, methyl acrylate, ethyl acrylate, methacrylic acid, acrylic acid, n-butyl acrylate, isobutyl acrylate, n-butyl methacrylate, isobutyl methacrylate, cyclohexyl acrylate, cyclohexyl methacrylate, isobornyl acrylate, isobornyl methacrylate, hydroxyethyl acrylate and hydroxyethyl methacrylate, and mixtures thereof.

According to a preferred embodiment, at least 50% by weight and preferably at least 60% by weight of the (meth)acrylic monomer (M1) is methyl methacrylate.

According to a first more preferred embodiment, at least 50% by weight, preferably at least 60% by weight, more preferably at least 70% by weight, advantageously at least 80% by weight and even more advantageously 90% by weight of the monomer (M1) is a mixture of methyl methacrylate with optionally at least one other monomer.

As regards the fibrous material used, it may be such as those presented previously. The fibrous material may notably be chosen from glass fibers or carbon fibers, and may be one-dimensional, two-dimensional or even three-dimensional in shape.

As regards the structure or composition of the thermoplastic composite, it comprises at least 20% by weight of fibrous material relative to the weight of the thermoplastic matrix, preferably at least 40% fibrous material, advantageously at least 50% fibrous material and more advantageously at least 55% fibrous material.

As regards the polymerization process used for obtaining the thermoplastic (meth)acrylic matrix, mention may be made of radical polymerization, anionic polymerization or photopolymerization.

The initiator (INIT) may, for example, be a radical initiator, activated by heat. The radical initiator may be chosen from a compound comprising a peroxy group or compounds comprising an azo group, and preferably from a compound comprising a peroxy group.

Preferably, the compound comprising a peroxy group comprises from 2 to 30 carbon atoms.

Preferably, the compound comprising a peroxy group is chosen from diacyl peroxides, peroxyesters, peroxydicarbonates, dialkyl peroxides, peroxyacetals, a hydroperoxide or a peroxy ketal.

The initiator may notably be chosen from diisobutyryl peroxide, cumyl peroxyneodecanoate, bis(3-methoxybutyl) peroxydicarbonate, 1,1,3,3-tetramethylbutyl peroxyneodecanoate, cumyl peroxyneoheptanoate, di-n-propyl peroxydicarbonate, tert-amyl peroxyneodecanoate, di-sec-butyl peroxydicarbonate, diisopropyl peroxydicarbonate, bis(4-tert-butylcyclohexyl) peroxydicarbonate, bis(2-ethylhexyl) peroxydicarbonate, tert-butyl peroxyneodecanoate, di-n-butyl peroxydicarbonate, dicetyl peroxydicarbonate, dimyristyl peroxydicarbonate, 1,1,3,3-tetramethylbutyl peroxypivalate, tert-butyl peroxyneoheptanoate, tert-amyl peroxypivalate, tert-butyl peroxypivalate, bis(3,5,5-trimethylhexanoyl) peroxide, dilauroyl peroxide, didecanoyl peroxide, 2,5-di methyl-2,5-bis(2-ethylhexanoylperoxy)hexane, 1,1,3,3-tetramethylbutyl peroxy-2-ethyl hexanoate, tert-amyl peroxy-2-ethyl hexanoate, dibenzoyl peroxide, tert-butyl peroxy-2-ethylhexanoate, tert-butyl peroxydiethylacetate, tert-butyl peroxyisobutyrate, 1,1-di(tert-butylperoxy)-3,3,5-trimethylcyclohexane, 1,1-di(tert-amylperoxy)cyclohexane, 1,1-di(tert-butylperoxy)cyclohexane, tert-amyl peroxy-2-ethylhexylcarbonate, tert-amyl peroxyacetate, tert-butyl peroxy-3,5,5-tri methyl hexanoate, 2,2-di(tert-butylperoxy)butane, tert-butyl peroxyisopropylcarbonate, tert-butyl peroxy-2-ethylhexylcarbonate, tert-amyl peroxybenzoate, tert-butyl peroxyacetate, butyl 4,4-di(tert-butylperoxy)valerate, tert-butyl peroxybenzoate, di-tert-amyl peroxide, dicumyl peroxide, bis(2-tert-butylperoxyisopropyl)benzene, 2,5-dimethyl-2,5-di(tert-butylperoxy)hexane, tert-butylcumyl peroxide, 2,5-dimethyl-2,5-di(tert-butylperoxy)hex-3-yne, di-tert-butyl peroxide, 3,6,9-triethyl-3,6,9-trimethyl-1,4,7-triperoxonane, 2,2′-azobisisobutyronitrile (AlBN), 2,2′-azobis(2-methylbutyronitrile), azobisisobutyramide, 2,2′-azobis(2,4-dimethylvaleronitrile), 1,1′-azodi(hexahydrobenzonitrile) or 4,4′-azobis(4-cyanopentanoic acid).

In a known manner, a mixture of initiators may be used, for example a mixture of a heat-activated initiator as above and an initiator activated by radiation absorption.

The proportion of radical initiator relative to the monomers in the mixture may notably range from 100 to 2000 ppm (by weight), preferably from 200 to 1000 ppm by weight.

The (meth)acrylic monomer(s) (M1) in the liquid composition LC1 represent at least 40% by weight, preferably 50% by weight, advantageously 60% by weight and more advantageously 65% by weight of the total liquid (meth)acrylic syrup. The (meth)acrylic monomer(s) (M1) in the liquid composition LC1 or the (meth)acrylic syrup are present in proportions of between 40% and 90% by weight and preferably between 45% and 85% by weight of the composition comprising one or more (meth)acrylic monomer(s) (M1) and the (meth)acrylic polymer (P1).

The (meth)acrylic polymer(s) (P1) in the liquid composition LC1 or the (meth)acrylic syrup are present in a proportion of at least 1% by weight, preferably at least 5%, more preferably at least 10% by weight, even more preferably at least 15%, advantageously at least 18% and more advantageously at least 20% by weight of the composition comprising one or more (meth)acrylic monomer(s) (M1) and the (meth)acrylic polymer (P1).

The (meth)acrylic polymer(s) (P1) in the liquid (meth)acrylic syrup LC1 are present in a proportion of not more than 50% by weight, preferably not more than 40% and advantageously not more than 30% by weight of the composition comprising the (meth)acrylic monomer(s) (M1) and the (meth)acrylic polymer (P1).

As regards the process for preparing the article, several processes may be used: lamination, pultrusion, infusion, vacuum bag molding, pressure bag molding, autoclave bag molding, resin transfer molding (RTM) and variants thereof, the press process, filament winding, compression molding or wet forming.

Advantageously, the composite article is prepared by resin transfer molding or infusion.

Resin transfer molding is a process using a two-sided mold set which forms both surfaces of the composite material. The lower side is a rigid mold. The upper side may be a rigid or flexible mold. Flexible molds may be composed of composite materials, silicone or extruded polymer films such as nylon. The two sides fit together to form a mold cavity. Resin transfer molding is characterized by the fact that the reinforcing materials and the electronic system are placed in this cavity, and the mold is closed before the matrix is introduced. Resin transfer molding comprises many variants, differing in the mechanical aspects of how the resin is introduced into the reinforcing material in the cavity. These variants comprise all the possibilities, from vacuum infusion to vacuum-assisted resin transfer molding (VARTM). This process may be performed either at ambient temperature or at a higher temperature. With an infusion process, the liquid prepolymer syrup must indeed have a viscosity suitable for the process for preparing the polymer composite material. The syrup is drawn into the fibrous material, which is present in a special mold, by applying a gentle vacuum. The liquid prepolymer syrup completely infuses and wets the fibrous material. One advantage of this process is the large amount of fibrous material in the composite.

Preferred processes for preparing composite articles are those in which the liquid resin of the matrix material not yet polymerized is transferred to the fibrous material more preferentially in a mold. This notably enables subsequent forming to be avoided.

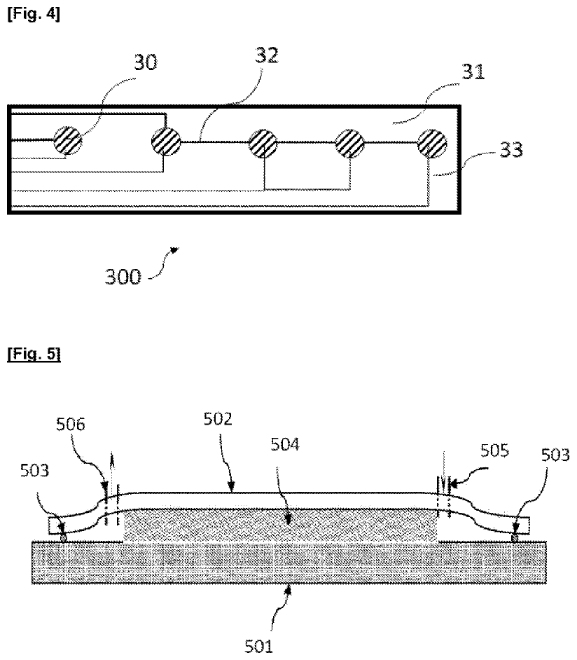

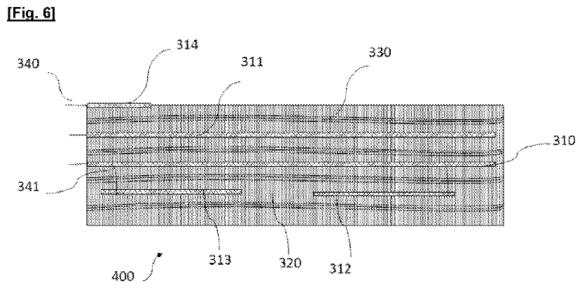

FIG. 5 represents a simplified diagram of the infusion process and of mold 500. The lower part 501 of the mold is made of a rigid material, while the upper part 502 of the mold is made of a flexible material which hermetically seals the mold using gaskets 503 ensuring its leaktightness.

The fibrous material and the electronic system 504 are arranged between the lower 501 and upper 502 parts of the mold. The liquid resin is dispensed through a dispensing pipe 505, which enters the mold, and a vacuum pipe 506. When a gentle vacuum is applied, the liquid resin infuses the fibrous material and the electronic system 504 placed between the two parts of the mold.

FIG. 6 represents a composite thermoplastic laminate 400 within which transducer arrays 310, 311, 312, notably printed circuits 300, such as that shown in FIG. 4, have been integrated in a thermoplastic matrix 320.

Thus, in this embodiment, fiber fabrics 330 have been stacked one on top of the other and transducer arrays 310, 311, 312 have been interposed.

This does not necessarily represent an actual case of stacking, but allows different transducer array arrangements to be exemplified within the volume of the composite thermoplastic laminate 400.

The printed transducer circuit may, as represented by circuit 310, be arranged right in the heart of the laminate, notably at the “neutral fiber” level, in such a way as to minimize tensile or compression phenomena for highly deformable articles. The printed transducer circuit may, as represented by circuits 311, 312, 313, be arranged in the volume but more peripherally than circuit 310.

In particular cases, the printed transducer circuit may be flush with the laminate surface, as represented by circuit 314.

The use of transducer circuits allows the number of electrical cables 340, 341 to be limited, and is relatively non-invasive.

### Recycling

In the context of the invention, the use of a composite article comprising a thermoplastic matrix, a thermoplastic piezoelectric polymer, and optionally including a fibrous reinforcing material, allows the amount of non-recyclable material to be significantly reduced to a strict minimum.

Thus, the composite article according to the invention may be at least partly, and preferably almost entirely, recycled.

Recycling is understood to be the recovery of at least some of the materials making up the article for a second use. This generally means grinding the article and/or reusing the thermoplastic polymers. This may also mean, at least according to certain embodiments, that some of the monomers used for the polymerization of thermoplastic polymers, notably the thermoplastic matrix, can be recovered.

Other particularly advantageous recycling methods have also already been disclosed for thermoplastic polymers, optionally (meth)acrylic polymers: microwave recycling, involving the presence of a compound which sensitizes to this type of depolymerization (see FR 3 080 625), recycling including a hydrolysis step (see FR 3 080 623), recycling by short depolymerization (see FR 3 080 622) or else recycling with an improved energy balance (FR 3 080 624).

### Specific Implementation Example

### Preparative Example 1: Screen Printing of a P(VDF-TrFE)-Based Array of Piezoelectric Transducers

An array of six transducers was printed using a DEK 248 semiautomatic screen-printing machine, equipped with a suction plate, on a 125 μm heat-stabilized PET substrate.

The substrate was first cleaned in a clean room using an ethanol-soaked cloth, then dried with an ionizing gun. Printing was performed as follows:
(i) Polyester screen printing of the lower electrodes, 3.14 cm², in PEDOT:PSS (Clevios Heraeus SV4 ink) then drying at 120° C. for 10 minutes in a ventilated oven;
(ii) Polyester screen printing of the piezoelectric layers, 3.8 cm², in P(VDF-TrFE) (Piezotech® FC20 Ink P) then drying at 120° C. for 20 minutes in a ventilated oven;
(iii) Polyester screen printing of the upper electrodes, 3.14 cm², in PEDOT:PSS (Clevios Heraeus SV4 ink) then drying at 120° C. for 10 minutes in a ventilated oven;
(iv) Polyester screen printing of the silver electrical tracks (Dupont ME604 ink), allowing the use of an electronic ribbon connector at the edge of the PET film, followed by drying at 120° C. for 10 minutes in a ventilated oven; and,
(v) Annealing at 140° C. for 10 min in a ventilated oven.

Each transducer was then individually polarized by application of a sinusoidal voltage, from 0 to 500 V, at a frequency of 1 Hz, with an increase of 25 V per period. Measurement of the current during the polarization step enables measurement of the remanent polarization, related to the piezoelectric properties, after computer processing. All the transducers have a remanent polarization of greater than 70 mC/m², indicating good ferro- and piezoelectric properties.

### Example 1: Production of a Composite Article Incorporating the Transducer Array According to Example 1

A conventional infusion assembly with a draining grid was implemented. The draining grid facilitates filling of the part.

The transducer array printed according to Preparative Example 1 was interleaved with six glass fabrics (Taffeta 600 g/m 2), measuring 21 cm×29.7 cm.

Particular attention was paid to the connectors, protected by Kapton adhesive tape, so as to keep them visible and prevent the resin from coming into contact therewith.

A syrup was prepared by dissolving 25% by weight of polymethyl methacrylate (PMMA V825 from the company Altuglas) in methyl methacrylate (MMA) in the presence of 325 ppm of AIBN (azobisisobutyronitrile) and 35 ppm of terpinolene (1,4-para-menthadiene). Dissolution took place at room temperature at 25° C. for 48 hours. The viscosity of the syrup solution was 513 mPa·s, measured at room temperature (25° C.) with a cone/plate rheometer from the company Brookfield. The prepolymer syrup formed was infused by means of a vacuum pump for transferring the syrup through the fabric. The sheet was impregnated by infusion for 3 minutes. The sheet impregnated by infusion was placed in an oven for 4 hours at 60° C. and an additional heating step of 30 minutes at 125° C. took place to terminate the polymerization of the PMMA (achieving a degree of monomer conversion of 100%).

The polymer composite was recovered by separation of the various films of the infusion and stripping from the mold.

Good adhesion between the piezoelectric transducer array and the composite matrix was observed.

The piezoelectric properties of each transducer are evaluated by:
A) verifying the generation of a voltage peak on an oscilloscope during a simulated impact with an impact hammer, indicating their functionality.
B) where appropriate, measuring their capacitance, using an LCR meter at 1 kHz; and

All the transducers show a voltage peak during simulated impact with the impact hammer and are thus regarded as being functional after manufacture of the composite article.

The results of the capacitance measurements are summarized in Table 1.

### Comparative Example 1: Production of a Composite Article Incorporating PVDF Transducers

Comparative Example 1 is performed in the same way as Example 1, except that the printed array of six P(VDF-TrFE) transducers is replaced with six PVDF film-based transducers (LDT1-028K from TE Connectivity) connected by electrical cables. The 12 electrical cables are assembled to form a web exiting from one side of the article.

No transducer is functional after the article has been manufactured during the simulated impact with the impact hammer.

### Comparative Example 2: Production of a Composite Article Incorporating PZT Transducers

Comparative Example 2 is performed in the same way as Example 1, except that the printed array of six P(VDF-TrFE) transducers is replaced with six PZT transducers (Murata 7BB-27-4) connected by electrical cables. The 12 electrical cables are assembled to form a web exiting from one side of the article.

Two transducers were found to be non-functional during the simulated impact with the impact hammer. It is likely that, due to their brittle nature, some transducers were broken during manufacture of the composite article and/or during propagation of the shock wave.

The results of the capacitance measurements are summarized in Table 1 (“-” indicates that no measurement was taken, as the transducer was not functional).

TABLE 1

| | Capacitance (nF), at 1 kHz, at 23° C. | | |
|---|---|---|---|
| Transducer | P(VDF-TrFE) | PVDF | PZT |
| 1 | 5.9 | — | — |
| 2 | 6.3 | — | 17.0 |
| 3 | 5.0 | — | 21.8 |
| 4 | 5.4 | — | 22.6 |
| 5 | 6.1 | — | — |
| 6 | 5.2 | — | 19.8 |

1. A composite article comprising at least one electronic system, integrated onto the surface or in the volume of a thermoplastic matrix and at least one reinforcing material,
said electronic system comprising at least one piezoelectric transducer and electrical signal transmission means;
said piezoelectric transducer comprising a piezoelectric polymer essentially consisting of repeating units derived from vinylidene fluoride (VDF) and vinylidene trifluoride (TrFE), the molar proportion of the unit derived from TrFE being from 15% to 50% relative to the total number of moles of the units derived from VDF and TrFE.

2. The article as claimed in claim 1, in which said thermoplastic matrix is a acrylic matrix.

3. The article as claimed in claim 1, in which said piezoelectric polymer has a molar proportion of TrFE-based repeating units of from 16% to 35%, relative to the total number of moles of units derived from VDF and TrFE.

4. The article as claimed in claim 1, in which the Curie temperature of the piezoelectric polymer is strictly greater than 80° C.

5. The article as claimed in claim 1, in which said at least one transducer is a fiber comprising an inner conductive core constituting a first electrode, an intermediate coating comprising said at least one piezoelectric polymer adhering to said conductive core, and an outer conductive coating constituting a second electrode.

6. The article as claimed in claim 1, in which said at least one transducer and/or the electrical signal transmission means are obtained via electronic printing methods on a substrate.

7. The article as claimed in claim 1, in which said transducer comprises a film of piezoelectric polymer.

8. The article as claimed in claim 1, in which the piezoelectric polymer has a thickness of from 1 micron to 50 microns.

9. The article as claimed in claim 1, comprising a plurality of piezoelectric transducers forming an array.

10. The article as claimed in claim 1, wherein said electronic system is integrated into the thermoplastic matrix via an operating process whose temperature does not exceed the Curie temperature of the piezoelectric polymer.

11. The article as claimed in claim 1, in which the reinforcing material is a material consisting of long or continuous fibers.

12. The article as claimed in claim 1, in which said electronic system is integrated into the thermoplastic matrix via an in-situ polymerization process.

13. The article as claimed in claim 1, chosen from a multilayer composite structure for hydrogen distribution or storage, a structure for a wind turbine blade, a rebar for concrete, or a battery pack.

14. The article as claimed in claim 1, which is suitable and intended for recycling.

15. A method of using an electronic system for monitoring the progress of a process (Process Monitoring) for integrating said electronic system into a thermoplastic matrix, the electronic system and the thermoplastic matrix being intended to form a composite article as claimed in claim 1.

16. A method of using the composite article as claimed in claim 1, for measuring and/or monitoring properties of said article.
